(19) United States
(12) Patent Application Publication
(10) Pub. No.: US 2025/0028003 A1
(43) Pub. Date: Jan. 23, 2025

(54) APPARATUS FOR DETECTING SOFT SHORTS OF A BATTERY CELL AND METHOD FOR THE SAME

(71) Applicants: HYUNDAI MOTOR COMPANY, Seoul (KR); Kia Corporation, Seoul (KR)

(72) Inventors: Yoon Sung CHOI, Hwaseong-si (KR); Yo Han BAEK, Anyang-si (KR); Sang Jin LEE, Goyang-si (KR); Hyo Kyung LEE, Anyang-si (KR); Yoo Hong JANG, Suwon-si (KR)

(73) Assignees: HYUNDAI MOTOR COMPANY, Seoul (KR); Kia Corporation, Seoul (KR)

(21) Appl. No.: 18/519,358

(22) Filed: Nov. 27, 2023

(30) Foreign Application Priority Data
Jul. 17, 2023 (KR) 10-2023-0092619

(51) Int. Cl. G01R 31/385; G01R 31/396; G01R 31/52

(52) U.S. Cl. CPC G01R 31/385; G01R 31/396; G01R 31/52

(57) ABSTRACT

An apparatus for detecting soft shorts of a battery cell and a method for the same are provided. The apparatus includes a sensor to measure voltages of a plurality of battery cells, and a controller to determine a slope of a voltage of each battery cell, the deviation of the slope of the voltage for each battery cell, and detect a battery cell, which has the soft shorts, of the plurality of battery cells, based on the slope and the deviation.

### CROSS-REFERENCE TO RELATED APPLICATION

The present application claims priority to Korean Patent Application No. 10-2023-0092619, filed on Jul. 17, 2023, the entire contents of which is incorporated herein for all purposes by this reference.

### BACKGROUND OF THE PRESENT DISCLOSURE

### Field of the Present Disclosure

The present disclosure relates to a technology of detecting soft shorts caused inside a battery cell provided in a vehicle.

### Description of Related Art

In general, a battery pack includes a plurality of battery cells generally forming an in-series structure and/or in-parallel structure. The battery cell includes a cathode current collector, an anode current collector, a separator, an active material, and an electrolyte, and is able to be repeatedly charged or discharged through an electrochemical reaction between components.

Furthermore, the battery pack includes a battery management system (BMS) to control power supply, measure electrical characteristics, such as a current and a voltage, control charging and discharging, control equalization of the voltages, estimate state of charge (SoC), or estimate state of health (SoH).

Such a BMS is maintained activated for a first time even after the start-up (e.g., the stop of the start-up of the engine) of the vehicle is terminated, and intermittently wakes up for a second time after the first time has elapsed. After the second time is deactivated, the BMS is deactivated.

Meanwhile, when self-discharging is caused inside the battery cell due to the internal soft shorts of the battery cell, the voltage of the battery cell may be degraded over time. However, it takes a long time for an operator to confirm a significant voltage drop.

Because the normal sensitivity of the voltage sensor is generally 2 mV, the operator may determine the occurrence of a significant voltage drop only when a voltage drop of at least 2 mV occurs.

For example, when soft shorts of 1000Ω are caused in the battery cell of 4 V, it takes about 100 hours for the voltage drop of 3 mV. Accordingly, it takes more time to finally diagnose that the battery cell has failed.

Accordingly, to diagnose the self-discharging of the battery cell due to the internal soft shorts, the vehicle needs to be maintained parked for a long time, that is, maintained while the battery cell does not supply power to a load for the long time. However, an event of leaving the vehicle for a long time may occur at a significantly low frequency. Accordingly, it is difficult to diagnose the self-discharging of the battery cell due to the internal soft shorts.

The information included in this Background of the present disclosure is only for enhancement of understanding of the general background of the present disclosure and may not be taken as an acknowledgement or any form of suggestion that this information forms the prior art already known to a person skilled in the art.

### BRIEF SUMMARY

Various aspects of the present disclosure are directed to providing an apparatus for detecting soft shorts of a battery cell, configured for periodically measuring a voltage of each battery cell with respect to the plurality of battery cells provided in the vehicle, of determining a slope of the voltage for each battery cell and a deviation of the slope of the voltage for each battery cell, and of detecting a battery cell having soft shorts, of the plurality of battery cells, based on the slope and the deviation, detecting the soft shorts caused in the battery cell with higher accuracy, even if the vehicle is not parked for a long time, and a method for the same.

Another aspect of the present disclosure provides an apparatus for detecting soft shorts of a battery cell, configured for periodically measuring a voltage of each battery cell with respect to a plurality of battery cells, of determining a first slope of the voltage for each battery cell for a first time and a first deviation of the first slope of the voltage for each battery cell, of determining a second slope of the voltage for each battery cell for a second time and a second deviation of the second slope of the voltage for each battery cell, and of detecting a battery cell having the soft shorts, based on the first slope of the voltage of each battery cell, and the first deviation, and the second slope of the voltage of each battery cell and the second deviation, detecting the soft shorts caused in the battery cell with higher accuracy, even if the vehicle is not parked for a long time, and a method for the same.

Another aspect of the present disclosure provides an apparatus for detecting soft shorts of a battery cell, configured for periodically measuring a voltage of each battery cell with respect to a plurality of battery cells, of determining a first slope of the voltage for each battery cell for a first time and a first deviation of the first slope of the voltage for each battery cell, of determining a second slope of the voltage for each battery cell for a second time and a second deviation of the second slope of the voltage for each battery cell, and of determining, as the battery cell having the soft shorts, a battery cell satisfying a condition that the difference between the first slope and the second slope exceeds the first threshold value, and the first deviation and the second deviation exceed a second threshold value, detecting the soft shorts caused in the battery cell with higher accuracy, even if the vehicle is not parked for a long time, and a method for the same.

Another aspect of the present disclosure provides an apparatus for detecting soft shorts of a battery cell, configured for periodically measuring a voltage of each battery cell with respect to a plurality of battery cells, of determining a first slope of the voltage for each battery cell for a first time and a first deviation of the first slope of the voltage for each battery cell, of determining a second slope of the voltage for each battery cell for a second time and a second deviation of the second slope of the voltage for each battery cell, and of determining, as the battery cell having the soft shorts, a battery cell satisfying a condition that the difference between the first slope and the second slope exceeds the first threshold value, and the first deviation and the second deviation exceed a second threshold value by a preset number of times or consecutively satisfying the condition by the preset number of times, detecting the soft shorts caused in the battery cell with higher accuracy, even if the vehicle is not parked for a long time, and a method for the same, detecting the soft shorts caused in the battery cell with higher accuracy, even if the vehicle is not parked for a long time, and a method for the same.

Another aspect of the present disclosure provides an apparatus for detecting soft shorts of a battery cell, configured for periodically measuring a voltage of each battery cell with respect to a plurality of battery cells, of determining a first slope of the voltage for each battery cell for a first time and a first deviation of the first slope of the voltage for each battery cell, of determining a second slope of the voltage for each battery cell for a second time and a second deviation of the second slope of the voltage for each battery cell, and of determining, as a battery cell having soft shorts, a battery cell satisfying a condition that the second slope is less than a third threshold value, and the second deviation exceeds a second threshold value, detecting the soft shorts caused in the battery cell with higher accuracy, even if the vehicle is not parked for a long time, and a method for the same.

Another aspect of the present disclosure provides an apparatus for detecting soft shorts of a battery cell, configured for periodically measuring a voltage of each battery cell with respect to a plurality of battery cells, of determining a first slope of the voltage for each battery cell for a first time and a first deviation of the first slope of the voltage for each battery cell, of determining a second slope of the voltage for each battery cell for a second time and a second deviation of the second slope of the voltage for each battery cell, and of determining, as a battery cell having soft shorts, a battery cell satisfying a condition that the second slope is less than a third threshold value, and the second deviation exceeds a second threshold value by a preset number of times or consecutively satisfying the condition by the preset number of times, detecting the soft shorts caused in the battery cell with higher accuracy, even if the vehicle is not parked for a long time, and a method for the same.

The technical problems to be solved by the present disclosure are not limited to the aforementioned problems, and any other technical problems not mentioned herein will be clearly understood from the following description by those skilled in the art to which the present disclosure pertains.

According to an aspect of the present disclosure, an apparatus for detecting soft shorts of a battery cell, may include a sensor to measure voltages of a plurality of battery cells, and a controller to determine a slope of a voltage of each battery cell, the deviation of the slope of the voltage for each battery cell, and detect a battery cell, which has soft shorts, of the plurality of battery cells, based on the slope and the deviation.

According to an exemplary embodiment of the present disclosure, the controller may determine a first slope of the voltage for each battery cell for a first time and a first deviation of the first slope of the voltage for each battery cell, determine a second slope of the voltage for each battery cell for a second time and a second deviation of the second slope of the voltage for each battery cell for the second time, and detect the battery cell having the soft sorts, based on the first slope of the voltage for each battery cell and the first deviation, and the second slope of the voltage for each battery cell and the second deviation.

According to an exemplary embodiment of the present disclosure, the controller may determine, as the battery cell having soft shorts, a battery cell satisfying a first condition that a difference between the first slope and the second slope exceeds a first threshold value and the first deviation and the second deviation exceed a second threshold value.

According to an exemplary embodiment of the present disclosure, the controller may determine, as the battery cell having soft shorts, a battery cell satisfying a first condition that a difference between the first slope and the second slope exceeds a first threshold value and the first deviation and the second deviation exceed a second threshold value by a preset number of times.

According to an exemplary embodiment of the present disclosure, the controller may determine, as the battery cell having soft shorts, a battery cell consecutively satisfying a first condition that a difference between the first slope and the second slope exceeds a first threshold value and the first deviation and the second deviation exceed a second threshold value by a preset number of times.

According to an exemplary embodiment of the present disclosure, the controller may determine, as the battery cell having soft shorts, a battery cell satisfying a second condition that the second slope is less than a third threshold value and the second deviation exceeds a second threshold value.

According to an exemplary embodiment of the present disclosure, the controller may determine, as the battery cell having soft shorts, a battery cell satisfying a second condition that the second slope is less than a third threshold value and the second deviation exceeds a second threshold value by a preset number of times.

According to an exemplary embodiment of the present disclosure, the controller may determine, as the battery cell having soft shorts, a battery cell consecutively satisfying a second condition that the second slope is less than a third threshold value and the second deviation exceeds a second threshold value by a preset number of times.

According to an exemplary embodiment of the present disclosure, the controller may determine, as a first time, from a time point at which a maximum voltage is measured with respect to each battery cell to a time point at which the controller is deactivated.

According to an exemplary embodiment of the present disclosure, the controller may determine, as a second time, from a time point at which a maximum voltage is measured with respect to each battery cell to a time point at which the controller is activated after being deactivated.

According to another aspect of the present disclosure, a method for detecting soft shorts of a battery cell, may include measuring, by a sensor, voltages of a plurality of battery cells, and determining, by a controller, a slope of a voltage of each battery cell, a deviation of the slope of the voltage for each battery cell, and detecting a battery cell, which has soft shorts, of the plurality of battery cells, based on the slope and the deviation.

According to an exemplary embodiment of the present disclosure, the detecting of the battery cell, which has soft shorts, may include determining, by the controller, a first slope of the voltage for each battery cell for a first time and a first deviation of the first slope of the voltage for each battery cell, determining, by the controller, a second slope of the voltage for each battery cell for a second time and a second deviation of the second slope of the voltage for each battery cell for the second time, and detecting, by the controller, the battery cell having the soft sorts, based on the first slope of the voltage for each battery cell and the first deviation, and the second slope of the voltage for each battery cell and the second deviation.

According to an exemplary embodiment of the present disclosure, the detecting of the battery cell, which has soft shorts, may include determining, by the controller, as the battery cell having soft shorts, a battery cell satisfying a first condition that a difference between the first slope and the second slope exceeds a first threshold value and the first deviation and the second deviation exceed a second threshold value.

According to an exemplary embodiment of the present disclosure, the detecting of the battery cell, which has soft shorts, may include determining, by the controller, as the battery cell having soft shorts, a battery cell satisfying a first condition that a difference between the first slope and the second slope exceeds a first threshold value and the first deviation and the second deviation exceed a second threshold value by a preset number of times.

According to an exemplary embodiment of the present disclosure, the detecting of the battery cell, which has soft shorts, may include determining, by the controller, as the battery cell having soft shorts, a battery cell consecutively satisfying a first condition that a difference between the first slope and the second slope exceeds a first threshold value and the first deviation and the second deviation exceed a second threshold value by a preset number of times.

According to an exemplary embodiment of the present disclosure, the detecting of the battery cell, which has soft shorts, may include determining, by the controller, as the battery cell having soft shorts, a battery cell satisfying a second condition that the second slope is less than a third threshold value and the second deviation exceeds a second threshold value.

According to an exemplary embodiment of the present disclosure, the detecting of the battery cell, which has soft shorts, may include determining, by the controller, as the battery cell having soft shorts, a battery cell satisfying a second condition that the second slope is less than a third threshold value and the second deviation exceeds a second threshold value by a preset number of times.

According to an exemplary embodiment of the present disclosure, the detecting of the battery cell, which has soft shorts, may include determining, by the controller, as the battery cell having soft shorts, a battery cell consecutively satisfying a second condition that the second slope is less than a third threshold value and the second deviation exceeds a second threshold value by a preset number of times.

According to an exemplary embodiment of the present disclosure, the determining of the first deviation of the first slope of the voltage for each battery cell may include determining, by the controller, as a first time, from a time point at which a maximum voltage is measured with respect to each battery cell to a time point at which the controller is deactivated.

According to an exemplary embodiment of the present disclosure, the determining of the second deviation of the second slope of the voltage for each battery cell may include determining, by the controller, as a second time, from a time point at which a maximum voltage is measured with respect to each battery cell to a time point at which the controller is activated after being deactivated.

The methods and apparatuses of the present disclosure have other features and advantages which will be apparent from or are set forth in more detail in the accompanying drawings, which are incorporated herein, and the following Detailed Description, which together serve to explain certain principles of the present disclosure.

### BRIEF DESCRIPTION OF THE DRAWINGS

FIG. 1 is a block diagram illustrating an apparatus for detecting soft shorts of a battery cell, according to an exemplary embodiment of the present disclosure;

FIG. 2 is a view exemplarily illustrating an operating duration of a controller provided in an apparatus for detecting soft shorts of a battery cell, according to an exemplary embodiment of the present disclosure;

FIG. 3 is a view exemplarily illustrating the process of determining a slope for a first time and a slope for a second time by a controller provided in an apparatus for detecting soft shorts of a battery cell, according to an exemplary embodiment of the present disclosure;

FIG. 4 is a view exemplarily illustrating a first deviation and a second deviation determined by a controller provided in an apparatus for detecting soft shorts of a battery cell according to an exemplary embodiment of the present disclosure;

FIG. 5 is a flowchart illustrating a method for detecting soft shorts of a battery cell, according to an exemplary embodiment of the present disclosure; and

FIG. 6 is a block diagram illustrating a computing system to execute a method for detecting soft shorts of a battery cell, according to an exemplary embodiment of the present disclosure.

It may be understood that the appended drawings are not necessarily to scale, presenting a somewhat simplified representation of various features illustrative of the basic principles of the present disclosure. The predetermined design features of the present disclosure as included herein, including, for example, specific dimensions, orientations, locations, and shapes will be determined in part by the particularly intended application and use environment.

In the figures, reference numbers refer to the same or equivalent portions of the present disclosure throughout the several figures of the drawing.

### DETAILED DESCRIPTION

Reference will now be made in detail to various embodiments of the present disclosure(s), examples of which are illustrated in the accompanying drawings and described below. While the present disclosure(s) will be described in conjunction with exemplary embodiments of the present disclosure, it will be understood that the present description is not intended to limit the present disclosure(s) to those exemplary embodiments of the present disclosure. On the other hand, the present disclosure(s) is/are intended to cover not only the exemplary embodiments of the present disclosure, but also various alternatives, modifications, equivalents and other embodiments, which may be included within the spirit and scope of the present disclosure as defined by the appended claims.

Hereinafter, various exemplary embodiments of the present disclosure will be described in detail with reference to accompanying drawings. In adding the reference numerals to the components of each drawing, it should be noted that the identical or equivalent component is designated by the identical numeral even when they are displayed on other drawings. Furthermore, in the following description of an exemplary embodiment of the present disclosure, a detailed description of well-known features or functions will be ruled out in order not to unnecessarily obscure the gist of the present disclosure.

In describing the components of the exemplary embodiment of the present disclosure, terms such as first, second, “A”, “B”, “(a)”, “(b)”, and the like may be used. These terms are merely intended to distinguish one component from another component, and the terms do not limit the nature, sequence or order of the constituent components. Furthermore, unless otherwise defined, all terms used herein, including technical or scientific terms, include the same meanings as those generally understood by those skilled in the art to which the present disclosure pertains. Such terms as those defined in a generally used dictionary are to be interpreted as having meanings equal to the contextual meanings in the relevant field of art, and are not to be interpreted as having ideal or excessively formal meanings unless clearly defined as having such in the present application.

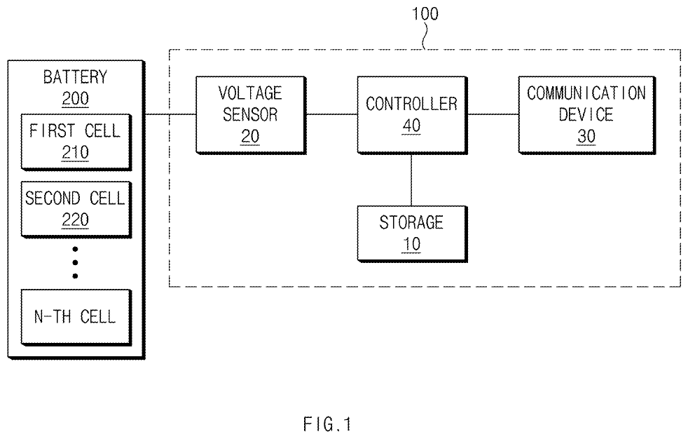

FIG. 1 is a flowchart illustrating a method for detecting soft shorts of a battery cell, according to an exemplary embodiment of the present disclosure.

As illustrated in FIG. 1, according to an exemplary embodiment of the present disclosure, an apparatus 100 for detecting soft shorts of a battery cell for battery 200 may include a storage 10, a voltage sensor 20, a communication device 30, and a controller 40. In the instant case, according to an exemplary embodiment of the present disclosure, components may be combined into each other to be implemented in one form, or some components may be omitted, depending on manners of reproducing apparatus for detecting soft shorts of a battery cell.

Regarding the components, the storage 10 may store various logics, various algorithms, and various programs required in a process of periodically measuring the voltage of each battery cell with respect to a plurality of battery cells 210 and 220 provided in a vehicle, of determining a slope of a voltage for each battery cell, the deviation of the slope of the voltage for each battery cell, and of detecting a battery cell, which has soft shorts, of the plurality of battery cells 210 and 220, based on the slope and the deviation.

The storage 10 may store various logics, various algorithms, and various programs required in a process of periodically measuring a voltage of each battery cell with respect to a plurality of battery cells 210 and 220 provided in a vehicle, of determining a first slope of a voltage for each battery cell for a first time, and a first deviation of the first slope of the voltage for each battery cell, of determining a second slope of a voltage for each battery cell for a second time, and a second deviation of the second slope of the voltage for each battery cell, and of detecting a battery cell having soft shorts based on the first slope of a voltage for each battery cell group and the first deviation, and the second slope of the voltage for each battery cell group and the second deviation.

The storage 10 may store various logics, various algorithms, and various programs required in a process of periodically measuring a voltage of each battery cell with respect to the plurality of battery cells 210 and 220 provided in the vehicle, of determining a first slope of the voltage for each battery cell for a first time and a first deviation of the first slope of the voltage for each battery cell, of determining a second slope of the voltage for each battery cell for a second time and a second deviation of the second slope of the voltage for each battery cell, and of determining, as the battery cell having the soft shorts, a battery cell satisfying a condition that the difference between the first slope and the second slope exceeds the first threshold value and both the first deviation and the second deviation exceed the second threshold value.

The storage 10 may store various logics, various algorithms, and various programs required in a process of periodically measuring a voltage of each battery cell with respect to the plurality of battery cells 210 and 220 provided in the vehicle, of determining a first slope of the voltage for each battery cell for a first time and a first deviation of the first slope of the voltage for each battery cell, of determining a second slope of the voltage for each battery cell for a second time and a second deviation of the second slope of the voltage for each battery cell, and of determining, as the battery cell having the soft shorts, a battery cell satisfying a condition that the difference between the first slope and the second slope exceeds the first threshold value, and the first deviation and the second deviation exceed a second threshold value by a preset number of times or consecutively satisfying the condition by the preset number of times.

The storage 10 may store various logics, various algorithms, and various programs required in a process of periodically measuring a voltage of each battery cell with respect to the plurality of battery cells 210 and 220 provided in the vehicle, of determining a first slope of the voltage for each battery cell for a first time and a first deviation of the first slope of the voltage for each battery cell, of determining a second slope of the voltage for each battery cell for a second time and a second deviation of the second slope for each battery cell, and of determining, as the battery cell having the soft shorts, a battery cell satisfying a condition that the second slope is less than a third threshold value, and the second deviation exceeds a second threshold value.

The storage 10 may store various logics, various algorithms, and various programs required in a process of periodically measuring a voltage of each battery cell with respect to the plurality of battery cells 210 and 220 provided in the vehicle, of determining a first slope of the voltage for each battery cell for a first time and a first deviation of the first slope of the voltage for each battery cell, of determining a second slope of the voltage for each battery cell for a second time and a second deviation of the second slope of the voltage for each battery cell, and of determining, as the battery cell having the soft shorts, a battery cell satisfying a condition that the second slope is less than the third threshold value, and the second deviation exceeds the second threshold value by a preset number of times, or satisfying consecutively the condition by the preset number of times.

The storage 10 may include at least one storage medium of a memory in a flash memory type, a hard disk type, a micro type, the type of a card (e.g., a Security Digital (SD) card or an eXtreme digital card), a Random Access Memory (RAM), a Static RAM (SRAM), a Read Only Memory (ROM), a Programmable ROM (PROM), an Electrically Erasable and Programmable ROM (EEPROM), a magnetic RAM (MRAM), a magnetic disk-type memory, or an optical disk-type memory.

The voltage sensor 20 may measure a voltage of each battery cell with respect to the plurality of battery cells 210 and 220. In the instant case, the voltage sensor 20 includes sensors in number corresponding to the number of the battery cells 210 and 220 so that one sensor measures the voltage of one battery cell. The voltage sensor 20 may be mounted in a battery management system (BMS) in addition to a cell monitoring unit (CMU).

The communication device 30, which is a module to provide a communication interface with a server, may include at least one of a mobile communication module, a wireless Internet module, or a short-range communication module. In the instant case, the server may perform the function of the apparatus 100 for detecting soft shorts.

The mobile communication module may make communication with a server over a mobile communication network constructed depending on technology standards or communication schemes for mobile communication. For example, the technology standards or communication schemes for mobile communication may include Global System for Mobile communication (GSM), Code Division Multi Access (CDMA), Code Division Multi Access 2000 (CDMA2000), Enhanced Voice-Data Optimized or Enhanced Voice-Data Only (EV-DO), Wideband CDMA (WCDMA), High Speed Downlink Packet Access (HSDPA), High Speed Uplink Packet Access (HSUPA), Long Term Evolution (LTE), or Long Term Evolution-Advanced (LTEA).

The wireless Internet module, which is a module for wireless Internet access, may make communication through Wireless LAN (WLAN), Wireless-Fidelity (Wi-Fi), Wi-Fi Direct, Digital Living Network Alliance (DLNA), Wireless Broadband (WiBro), Worldwide Interoperability for Microwave Access (WiMAX), High Speed Downlink Packet Access (HSDPA), High Speed Uplink Packet Access (HSUPA), Long Term Evolution (LTE), or Long Term Evolution-Advanced (LTE-A).

The short-range communication module may support short-range communication with the server through at least one of Bluetooth™, Radio Frequency Identification (RFID), Infrared Data Association (IrDA), Ultra Wideband (UWB), ZigBee, Near Field Communication (NFC), or Wireless Universal Serial Bus (USB).

The controller 40 may perform the overall control so that the components normally perform the respective functions. Furthermore, the controller 40 may be implemented in a form of hardware or software, and may be implemented in a form of the combination of the hardware and the software. The controller 40 may be implemented with a micro-processor, but the present disclosure is not limited thereto.

The controller 40 may be configured for controlling the voltage sensor 20 to periodically measure the voltage of each battery cell with respect to the plurality of battery cells 210 and 220 provided in the vehicle.

The controller 40 may be configured to determine a slope of a voltage of each battery cell, the deviation of the slope of the voltage for each battery cell, and may detect a battery cell, which has soft shorts, of the plurality of battery cells 210 and 220 based on the slope and the deviation.

In detail, the controller 40 may be configured to determine a first slope of a voltage for each battery cell for a first time, and a first deviation of the first slope of the voltage for the battery cell groups, of determining a second slope of a voltage for each battery cell for a second time, and a second deviation of the second slope of the voltage for the battery cell groups, and of detecting a battery cell having soft shorts based on the first slope of the voltage for each battery cell group and the first deviation, and the second slope of the voltage for each battery cell group and the second deviation.

For example, the controller 40 may determine, as a battery cell having soft shorts, a battery cell satisfying a first condition that the difference between the first slope and the second slope exceeds the first threshold value (e.g., ‘−0.07’) and both the first deviation and the second deviation exceed the second threshold value (e.g., ‘3’). In the instant case, the controller 40 may determine, as the battery cell having the soft shorts, a battery cell satisfying the first condition by a preset number of times or consecutively satisfying the first condition by the preset number of times.

For example, the controller 40 may determine, as a battery cell having soft shorts, a battery cell satisfying a second condition that the second slope is less than a third threshold value (e.g., ‘−0.4’), and the second deviation exceeds the second threshold value (e.g., ‘3’). In the instant case, the controller 40 may determine, as the battery cell having the soft shorts, a battery cell satisfying the second condition by a preset number of times or consecutively satisfying the first condition by the preset number of times.

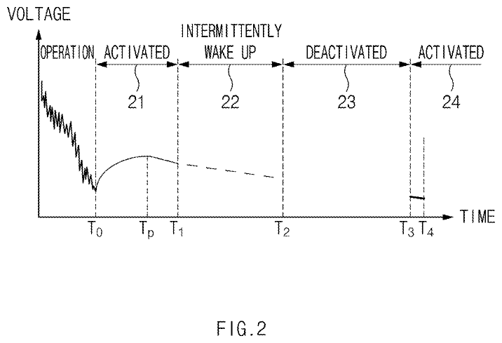

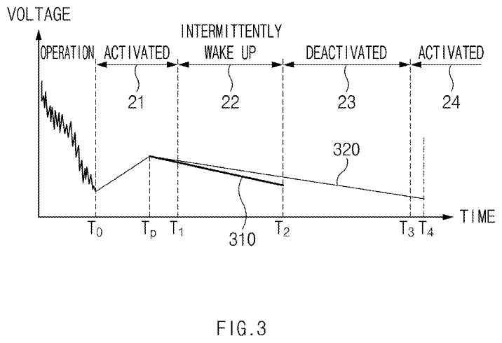

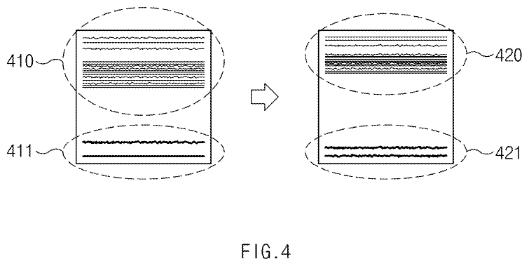

Hereinafter, the operation of the controller 40 will be described in detail with reference to FIG. 2, FIG. 3 and FIG. 4.

FIG. 2 is a view exemplarily illustrating an operating duration of a controller provided in an apparatus for detecting soft shorts of a battery cell according to an exemplary embodiment of the present disclosure.

As illustrated in FIG. 2, a vertical axis represents a voltage, a horizontal axis represents a time, T₀ indicates the time point (i.e., the startup of the engine is stopped) at which the driving of the vehicle is terminated, T₁ indicates a time point at which the controller 40 enters an intermittently wakes up mode, T₂ indicates a time point at which the controller 40 is deactivated, T₃ indicates a time point at which the controller 40 is activated, and T₄ indicates a time point at which the operation of the engine is started. In the instant case, the time period to T₁ and T₂ from T₀ is a preset time. Furthermore, T₃ may indicate a time point at which the controller 40 is activated, as the door of the vehicle is open, a seating signal, a seat belt fastening signal, or a Bluelink starting signal is applied, or the door lock of the vehicle is related.

Reference numeral ‘21’ indicates a duration in which the controller 400 maintains an activation state, reference numeral ‘22’ indicates a duration in which the controller 400 maintains the intermittently wakes up mode, reference numeral ‘23’ indicates a duration in which the controller 400 maintains a deactivation state, and reference numeral ‘24’ indicates a duration in which the controller 400 maintains the activation state again.

The controller 400 may measure the maximum voltage at the time point of Tₚ with respect to each battery cell in the activation duration 21, may detect the voltage for each battery cell only in the wake up state in the intermittently wakes up duration 22, may not detect the voltage for each battery cell voltage in the deactivation duration 23, and may detect the voltage for the battery cell in the secondary activation duration 24. In the instant case, the controller 400 detects the voltage for each battery cell only until the start of the engine is started in the secondary activation duration 24. This is because the soft shorts of the battery cell may not be detected when the start of the engine is started.

FIG. 3 is a view exemplarily illustrating the process of determining a slope for a first time and a slope for a second time by a controller provided in an apparatus for detecting soft shorts of a battery cell, according to an exemplary embodiment of the present disclosure.

As illustrated in FIG. 3, the controller 40 may determine, as a first time, a time period from a time point (Tₚ) at which the maximum voltage is measured with respect to each battery cell, to a time point (T₂) at which the controller 40 is deactivated, and may be configured to determine the first slope 310 of the voltage for each battery cell for the first time.

As illustrated in FIG. 3, the controller 40 may determine, as a second time, a time period from a time point (Tₚ) at which the maximum voltage is measured with respect to each battery cell, to a time point (T₃) at which the controller 40 is activated after being deactivated, and may be configured to determine the second slope 320 of the voltage for each battery cell for the second time. In the instant case, a time point, at which the second time is terminated, may be determined to any time point between (T₃(and (T₄(.

The controller 40 may find the average of first slopes determined with respect to each battery cell, and may be configured to determine the first deviation indicating the difference from the average of first slopes. Furthermore, the controller 40 may find the average of second slopes determined with respect to each battery cell, and may be configured to determine the second deviation indicating the difference from the average of second slopes. For example, the first deviation and the second deviation are as illustrated in FIG. 4.

FIG. 4 is a view exemplarily illustrating a first deviation and a second deviation determined by a controller provided in an apparatus for detecting soft shorts of a battery cell according to an exemplary embodiment of the present disclosure.

As illustrated in FIG. 4, reference numeral ‘410’ indicates the group of normal battery cells, and reference numeral ‘411’ indicates the group of abnormal battery cells, in terms of the deviation of the first slopes determined for each battery cell for the first time.

As illustrated in FIG. 4, reference numeral ‘420’ indicates the group of normal battery cells, and reference numeral ‘421’ indicates the group of abnormal battery cells, in terms of the deviation of the second slopes determined for each battery cell for the second hour.

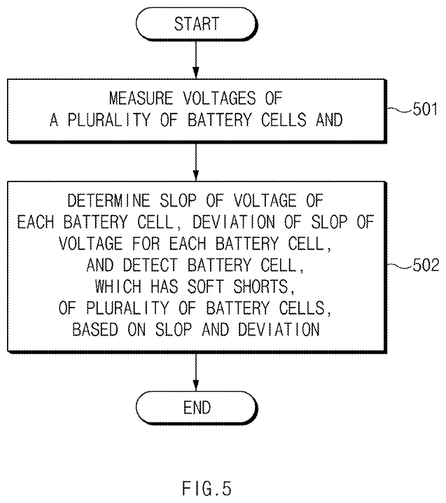

FIG. 5 is a flowchart illustrating a method for detecting soft shorts of a battery cell, according to an exemplary embodiment of the present disclosure.

First, the voltage sensor 20 measures the voltages of the plurality of battery cells (501).

The controller 40 may be configured to determine a slope of a voltage of each battery cell, the deviation of the slope of the voltage for each battery cell, and may detect a battery cell, which has soft shorts, of the plurality of battery cells 210 and 220 based on the slope and the deviation (502). The controller 40 may be configured to determine the first slope of the voltage for each battery cell for the first time and the first deviation of the first slope of the voltage for each battery cell, and of determining the second slope of the voltage for each battery cell for the second time and the second deviation of the second slope of the voltage for each battery cell for the second time, and detecting the battery cell having the soft sorts, based on the first slope of the voltage for each battery cell and the first deviation, and the second slope of the voltage for each battery cell and the second deviation.

The communication device 30 may be configured to transmit information to the server about the battery cell in which the soft shorts occurred.

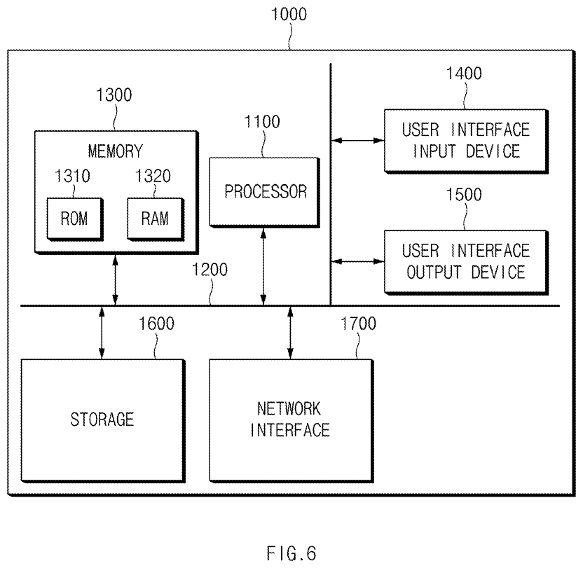

FIG. 6 is a block diagram illustrating a computing system to execute a method for detecting soft shorts of a battery cell, according to an exemplary embodiment of the present disclosure.

Referring to FIG. 6, according to an exemplary embodiment of the present disclosure, the method for collecting the training image of the deep learning mode may be implemented through the computing system. A computing system 1000 may include at least one processor 1100, a memory 1300, a user interface input device 1400, a user interface output device 1500, a storage 1600, and a network interface 1700, which are connected to each other via a system bus 1200.

The processor 1100 may be a central processing unit (CPU) or a semiconductor device for processing instructions stored in the memory 1300 and/or the storage 1600. Each of the memory 1300 and the storage 1600 may include various types of volatile or non-volatile storage media. For example, the memory 1300 may include a read only memory (ROM; see 1310) and a random access memory (RAM; see 1320).

Thus, the operations of the methods or algorithms described in connection with the exemplary embodiments included in the present disclosure may be directly implemented with a hardware module, a software module, or the combinations thereof, executed by the processor 1100. The software module may reside on a storage medium (i.e., the memory 1300 and/or the storage 1600), such as a RAM, a flash memory, a ROM, an erasable and programmable ROM (EPROM), an electrically EPROM (EEPROM), a register, a hard disc, a removable disc, or a compact disc-ROM (CD-ROM). The exemplary storage medium may be coupled to the processor 1100. The processor 1100 may read out information from the storage medium and may write information in the storage medium. Alternatively, the storage medium may be integrated with the processor 1100. The processor 1100 and the storage medium may reside in an application specific integrated circuit (ASIC). The ASIC may reside in a user terminal. Alternatively, the processor 1100 and the storage medium may reside as separate components of the terminal of the user.

The above description is merely an example of the technical idea of the present disclosure, and various modifications and modifications may be made by one skilled in the art without departing from the essential characteristic of the present disclosure. Therefore, the exemplary embodiments of the present disclosure are provided to explain the spirit and scope of the present disclosure, but not to limit them, so that the spirit and scope of the present disclosure is not limited by the embodiments. The scope of the present disclosure should be construed based on the accompanying claims, and all the technical ideas within the scope equivalent to the claims should be included in the scope of the present disclosure.

As described, above, according to an exemplary embodiment of the present disclosure, the voltage of each battery cell may be periodically measured with respect to the plurality of battery cells provided in the vehicle, the slope of the voltage for each battery cell and the deviation of the slope of the voltage for each battery cell may be determined, and a battery cell having soft shorts of the plurality of battery cells may be detected based on the slope and the deviation, detecting the soft shorts caused in the battery cell with higher accuracy, even if the vehicle is not parked for a long time.

In various exemplary embodiments of the present disclosure, each operation described above may be performed by a control device, and the control device may be configured by a plurality of control devices, or an integrated single control device.

In various exemplary embodiments of the present disclosure, the memory and the processor may be provided as one chip, or provided as separate chips.

Furthermore, the terms such as “unit”, “module”, etc. included in the specification mean units for processing at least one function or operation, which may be implemented by hardware, software, or a combination thereof.

For convenience in explanation and accurate definition in the appended claims, the terms “upper”, “lower”, “inner”, “outer”, “up”, “down”, “upwards”, “downwards”, “front”, “rear”, “back”, “inside”, “outside”, “inwardly”, “outwardly”, “interior”, “exterior”, “internal”, “external”, “forwards”, and “backwards” are used to describe features of the exemplary embodiments with reference to the positions of such features as displayed in the figures. It will be further understood that the term “connect” or its derivatives refer both to direct and indirect connection.

The term “and/or” may include a combination of a plurality of related listed items or any of a plurality of related listed items. For example, “A and/or B” includes all three cases such as “A”, “B”, and “A and B”.

In the present specification, unless stated otherwise, a singular expression includes a plural expression unless the context clearly indicates otherwise.

In exemplary embodiments of the present disclosure, “at least one of A and B” may refer to “at least one of A or B” or “at least one of combinations of at least one of A and B”. Furthermore, “one or more of A and B” may refer to “one or more of A or B” or “one or more of combinations of one or more of A and B”.

In the exemplary embodiment of the present disclosure, it should be understood that a term such as “include” or “have” is directed to designate that the features, numbers, steps, operations, elements, parts, or combinations thereof described in the specification are present, and does not preclude the possibility of addition or presence of one or more other features, numbers, steps, operations, elements, parts, or combinations thereof.

The foregoing descriptions of specific exemplary embodiments of the present disclosure have been presented for purposes of illustration and description. They are not intended to be exhaustive or to limit the present disclosure to the precise forms disclosed, and obviously many modifications and variations are possible in light of the above teachings. The exemplary embodiments were chosen and described in order to explain certain principles of the invention and their practical application, to enable others skilled in the art to make and utilize various exemplary embodiments of the present disclosure, as well as various alternatives and modifications thereof. It is intended that the scope of the present disclosure be defined by the Claims appended hereto and their equivalents.

What is claimed is:

1. An apparatus for detecting soft shorts of a battery cell, the apparatus comprising:
a sensor configured for measuring voltages of a plurality of battery cells; and
a controller operatively connected to the sensor and configured to determine a slope of a voltage of each battery cell, a deviation of the slope of the voltage for each battery cell, and detect a battery cell, which has the soft shorts, of the plurality of battery cells, based on the determined slope and the determined deviation.

2. The apparatus of claim 1, wherein in the determining of the slope of the voltage of each battery cell, the controller is configured to:
determine a first slope of the voltage for each battery cell for a first time and a first deviation of the first slope of the voltage for each battery cell;
determine a second slope of the voltage for each battery cell for a second time and a second deviation of the second slope of the voltage for each battery cell for the second time; and
detect the battery cell having the soft sorts, based on the first slope of the voltage for each battery cell and the first deviation, and the second slope of the voltage for each battery cell and the second deviation.

3. The apparatus of claim 2, wherein the controller is further configured to:
determine, as the battery cell having the soft shorts, a battery cell satisfying a first condition that a difference between the first slope and the second slope exceeds a first threshold value and the first deviation and the second deviation exceed a second threshold value.

4. The apparatus of claim 2, wherein the controller is further configured to:
determine, as the battery cell having the soft shorts, a battery cell satisfying a first condition that a difference between the first slope and the second slope exceeds a first threshold value and the first deviation and the second deviation exceed a second threshold value by a preset number of times.

5. The apparatus of claim 2, wherein the controller is further configured to:
determine, as the battery cell having the soft shorts, a battery cell consecutively satisfying a first condition that a difference between the first slope and the second slope exceeds a first threshold value and the first deviation and the second deviation exceed a second threshold value by a preset number of times.

6. The apparatus of claim 2, wherein the controller is further configured to:
determine, as the battery cell having the soft shorts, a battery cell satisfying a second condition that the second slope is less than a third threshold value and the second deviation exceeds a second threshold value.

7. The apparatus of claim 2, wherein the controller is further configured to:
determine, as the battery cell having the soft shorts, a battery cell satisfying a second condition that the second slope is less than a third threshold value and the second deviation exceeds a second threshold value by a preset number of times.

8. The apparatus of claim 2, wherein the controller is further configured to:
determine, as the battery cell having the soft shorts, a battery cell consecutively satisfying a second condition that the second slope is less than a third threshold value and the second deviation exceeds a second threshold value by a preset number of times.

9. The apparatus of claim 2, wherein the controller is further configured to:
determine, as a first time, from a time point at which a maximum voltage is measured with respect to each battery cell to a time point at which the controller is deactivated.

10. The apparatus of claim 2, wherein the controller is further configured to:
determine, as a second time, from a time point at which a maximum voltage is measured with respect to each battery cell to a time point at which the controller is activated after being deactivated.

11. A method for detecting soft shorts of a battery cell, the method comprising:
measuring, by a sensor, voltages of a plurality of battery cells; and
determining, by a controller operatively connected to the sensor, a slope of a voltage of each battery cell, a deviation of the slope of the voltage for each battery cell, and detecting a battery cell, which has the soft shorts, of the plurality of battery cells, based on the slope and the deviation.

12. The method of claim 11, wherein the detecting of the battery cell, which has the soft shorts, includes:
determining, by the controller, a first slope of the voltage for each battery cell for a first time and a first deviation of the first slope of the voltage for each battery cell;
determining, by the controller, a second slope of the voltage for each battery cell for a second time and a second deviation of the second slope of the voltage for each battery cell for the second time; and
detecting, by the controller, the battery cell having the soft sorts, based on the first slope of the voltage for each battery cell and the first deviation, and the second slope of the voltage for each battery cell and the second deviation.

13. The method of claim 12, wherein the detecting of the battery cell, which has the soft shorts, includes:
determining, by the controller, as the battery cell having the soft shorts, a battery cell satisfying a first condition that a difference between the first slope and the second slope exceeds a first threshold value and the first deviation and the second deviation exceed a second threshold value.

14. The method of claim 12, wherein the detecting of the battery cell, which has the soft shorts, includes:
determining, by the controller, as the battery cell having the soft shorts, a battery cell satisfying a first condition that a difference between the first slope and the second slope exceeds a first threshold value and the first deviation and the second deviation exceed a second threshold value by a preset number of times.

15. The method of claim 12, wherein the detecting of the battery cell, which has the soft shorts, includes:
determining, by the controller, as the battery cell having the soft shorts, a battery cell consecutively satisfying a first condition that a difference between the first slope and the second slope exceeds a first threshold value and the first deviation and the second deviation exceed a second threshold value by a preset number of times.

16. The method of claim 12, wherein the detecting of the battery cell, which has the soft shorts, includes:
determining, by the controller, as the battery cell having the soft shorts, a battery cell satisfying a second condition that the second slope is less than a third threshold value and the second deviation exceeds a second threshold value.

17. The method of claim 12, wherein the detecting of the battery cell, which has the soft shorts, includes:
determining, by the controller, as the battery cell having the soft shorts, a battery cell satisfying a second condition that the second slope is less than a third threshold value and the second deviation exceeds a second threshold value by a preset number of times.

18. The method of claim 12, wherein the detecting of the battery cell, which has the soft shorts, includes:
determining, by the controller, as the battery cell having the soft shorts, a battery cell consecutively satisfying a second condition that the second slope is less than a third threshold value and the second deviation exceeds a second threshold value by a preset number of times.

19. The method of claim 12, wherein the determining of the first deviation of the first slope of the voltage for each battery cell includes:
determining, by the controller, as a first time, from a time point at which a maximum voltage is measured with respect to each battery cell to a time point at which the controller is deactivated.

20. The method of claim 12, wherein the determining of the second deviation of the second slope of the voltage for each battery cell includes:
determining, by the controller, as a second time, from a time point at which a maximum voltage is measured with respect to each battery cell to a time point at which the controller is activated after being deactivated.
